(19) United States
(12) Patent Application Publication
(10) Pub. No.: US 2016/0128234 A1
(43) Pub. Date: May 5, 2016

(54) COOLING DEVICE AND ELECTRONIC APPARATUS

(71) Applicant: FUJITSU LIMITED, Kawasaki-shi (JP)

(72) Inventors: Kenichi UESUGI, Yokohama (JP); Yoshihisa NAKAGAWA, Yokohama (JP); Hiromu SHOJI, Kawasaki (JP); Atsushi KANEKO, Yokohama (JP); Toshimitsu KOBAYASHI, Otawara (JP); Hideki SONOBE, Yokosuka (JP); Hiroshi NAKAMURA, Kawasaki (JP)

(21) Appl. No.: 14/924,577

(22) Filed: Oct. 27, 2015

(30) Foreign Application Priority Data
Oct. 30, 2014 (JP) 2014-221485

(51) Int. Cl. H05K 7/20; F28D 15/02

(52) U.S. Cl. CPC H05K 7/20336; F28D 15/0275; H05K 7/20327

(57) ABSTRACT

A cooling device including: a heat receiver in which a working fluid is enclosed, a heat sink in which the working fluid is enclosed, an air tube made of metal so as to have flexibility, the air tube coupling the heat receiver and the heat sink, the air tube in which the working fluid of a gas phase flows through, and a liquid tube made of metal so as to have flexibility, the liquid tube coupling the heat receiver and the heat sink, the liquid tube in which the working fluid of a liquid phase flows through.

### CROSS-REFERENCE TO RELATED APPLICATION

This application is based upon and claims the benefit of priority of the prior Japanese Patent Application No. 2014-221485, filed on Oct. 30, 2014, the entire contents of which are incorporated herein by reference.

### FIELD

The embodiments discussed herein are related to a cooling device and an electronic apparatus.

### BACKGROUND

There is a circulation type heat pipe which forms a circulation flow path configured of an evaporating section, a condensing section, a vapor tube, and a liquid return tube, and is provided with a wick and a liquid flow path on an inside of the liquid return tube.

Furthermore, there is a heat radiation structure of a cooling device which includes a heat absorber and a heat radiator, a first pipe, and a second pipe, in which the second pipe includes a capillary structure.

Furthermore, there is a loop heat pipe which includes an evaporating section, a condensing section, a vapor tube, and a liquid return tube, and is provided with a wick on insides of the evaporating section, the condensing section, and the liquid return tube.

Furthermore, there is a loop type heat pipe in which an evaporating tube and a liquid tube coupling an evaporator and a condenser are configured of an elastic body and have flexibility.

Furthermore, there is a heat pipe in which a wick within a sealed container formed of a flexible cable passing through respective insides of a heat receiving plate and a heat radiation plate is formed of a braided wire having elasticity.

Japanese Laid-open Patent Publication No. 11-95873, Japanese Registered Utility Model No. 3169627, Japanese Laid-open Patent Publication No. 2008-281275, Japanese Laid-open Patent Publication No. 11-95873, and Japanese Laid-open Patent Publication No. 2007-108228 are examples of the related art.

### SUMMARY

According to an aspect of the invention, a cooling device includes a heat receiver in which a working fluid is enclosed, a heat sink in which the working fluid is enclosed, an air tube made of metal so as to have flexibility, the air tube coupling the heat receiver and the heat sink, the air tube in which the working fluid of a gas phase flows through, and a liquid tube made of metal so as to have flexibility, the liquid tube coupling the heat receiver and the heat sink, the liquid tube in which the working fluid of a liquid phase flows through.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a perspective view illustrating a cooling device of a first embodiment;

FIG. 2 is an exploded perspective view illustrating a heat receiving section of the cooling device of the first embodiment;

FIG. 3 is a sectional view that is taken along line 3-3 of FIG. 1 illustrating the heat receiving section of the cooling device of the first embodiment;

FIG. 4 is an exploded perspective view illustrating a heat radiation section of the cooling device of the first embodiment;

FIG. 5 is a sectional view that is taken along line 5-5 of FIG. 1 illustrating the heat radiation section of the cooling device of the first embodiment;

FIG. 6 is a sectional view illustrating a cross section of an air tube of the cooling device of the first embodiment along a longitudinal direction;

FIG. 7 is a sectional view that is taken along line 7-7 of FIG. 6 illustrating the air tube of the cooling device of the first embodiment;

FIG. 8 is a sectional view illustrating a cross section of a liquid tube of the cooling device of the first embodiment along a longitudinal direction;

FIG. 9 is a sectional view that is taken along line 9-9 of FIG. 8 illustrating the liquid tube of the cooling device of the first embodiment;

FIG. 10 is a perspective view illustrating an electronic apparatus of the first embodiment by breaking a part of a housing;

FIG. 11 is a perspective view illustrating the electronic apparatus of the first embodiment by breaking a part of the housing;

FIG. 12 is a perspective view illustrating an electronic apparatus of a second embodiment by breaking a part of a housing;

FIG. 13 is a perspective view illustrating the electronic apparatus of the second embodiment by breaking a part of the housing;

FIG. 14 is a perspective view illustrating a cooling device of a third embodiment;

FIG. 15 is an exploded perspective view illustrating a heat radiation section of the cooling device of the third embodiment;

FIG. 16 is a sectional view illustrating the heat radiation section of the cooling device of the third embodiment together with an air tube and an air tube cover;

FIG. 17 is a sectional view illustrating the heat radiation section of the cooling device of the third embodiment together with a liquid tube and a liquid tube cover;

FIG. 18 is a sectional view that is taken along line 18-18 of FIG. 6 illustrating the air tube and the air tube cover of the cooling device of the third embodiment;

FIG. 19 is a sectional view that is taken along line 19-19 of FIG. 6 illustrating the liquid tube and the liquid tube cover of the cooling device of the third embodiment;

FIG. 20 is a perspective view illustrating an electronic apparatus of the third embodiment by breaking a part of a housing;

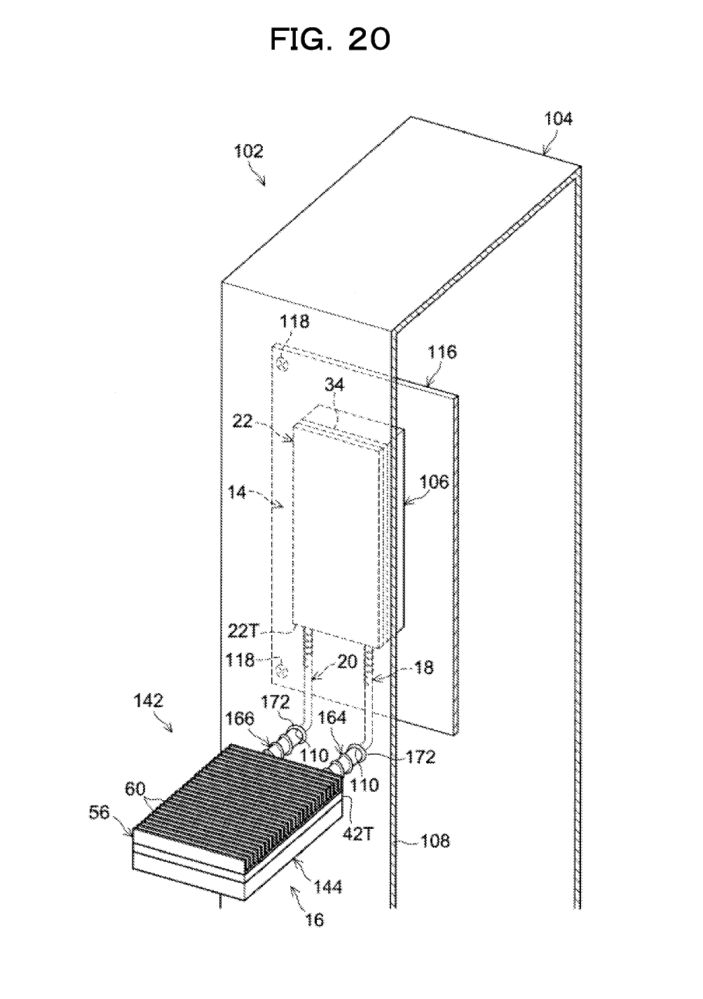

FIG. 21 is a perspective view illustrating an electronic apparatus of a fourth embodiment by breaking a part of a housing;

FIG. 22 is a sectional view illustrating the electronic apparatus of the fourth embodiment; and

FIG. 23 is a perspective view of a cooling device of a fifth embodiment.

### DESCRIPTION OF EMBODIMENTS

In a cooling device that circulates a working fluid by coupling (or connecting) a heat receiving section (or a heat receiver) and a heat radiation section (or a heat sink) by an air tube and a liquid tube, it is preferable to suppress leakage of the working fluid to the outside caused by passing through the air tube and the liquid tube.

Furthermore, it is preferable that a degree of freedom in arrangement of the heat receiving section and the heat radiation section is increased depending on an arrangement location of the cooling device.

An object of one aspect of a disclosed technique of this application is to increase the degree of freedom of the arrangement of the heat receiving section and the heat radiation section and suppress leakage of the working fluid caused by passing through the air tube and the liquid tube.

A first embodiment will be described with reference to the drawings.

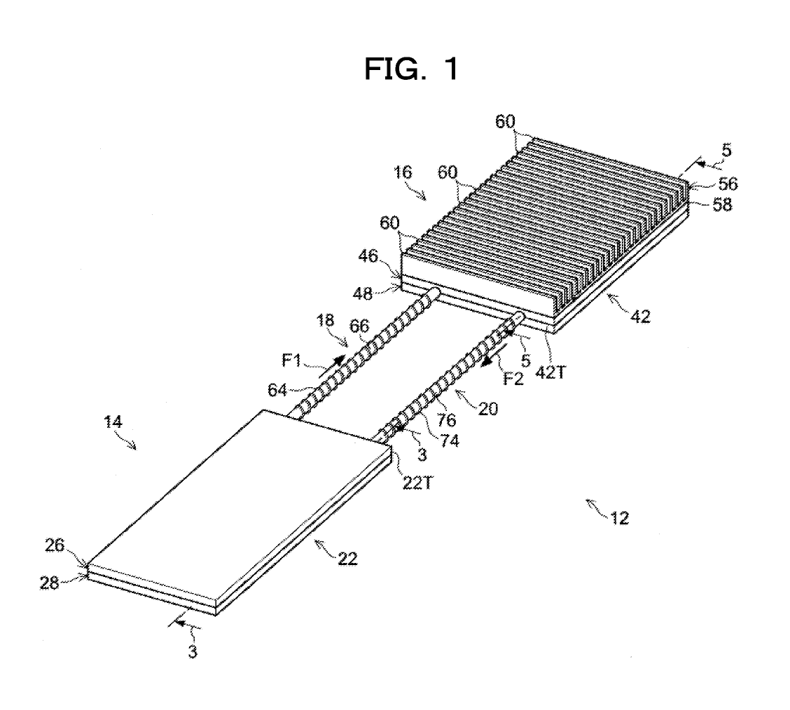

As illustrated in FIG. 1, a cooling device 12 of the first embodiment has a heat receiving section 14, a heat radiation section 16, an air tube 18, and a liquid tube 20.

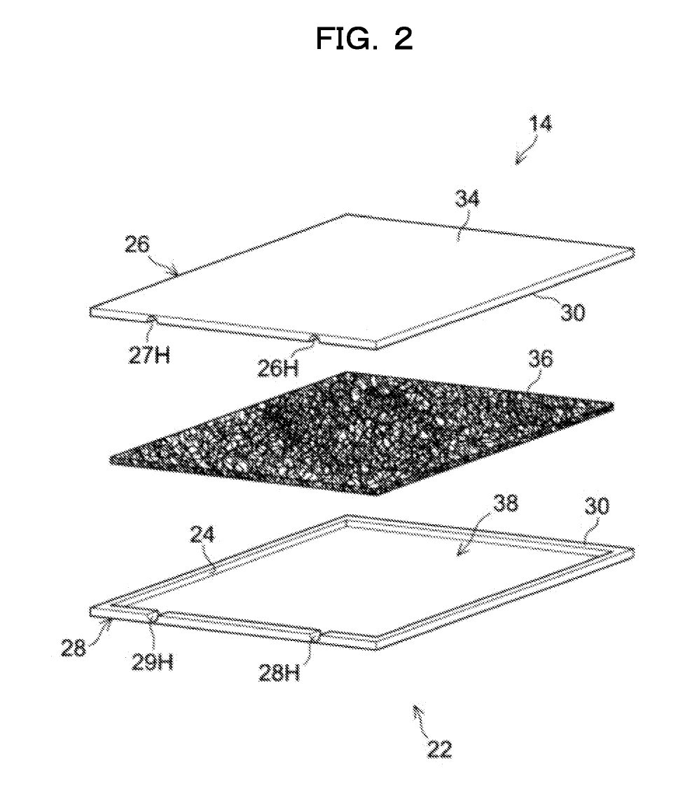

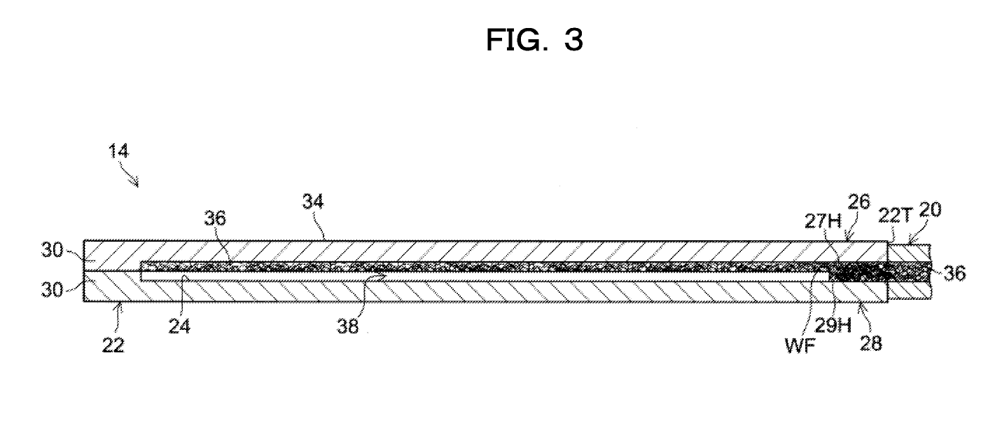

The heat receiving section 14 has a heat receiving plate 22 having a flat rectangular parallelepiped shape. Also as illustrated in FIGS. 2 and 3 in detail, an inside of the heat receiving plate 22 is a hollow storage section 24. The storage section 24 stores a working fluid WF in a sealed state. As the working fluid WF, water, alcohol, and the like may be exemplified.

The heat receiving plate 22 of the embodiment has an upper plate 26 and a lower plate 28. The upper plate 26 and the lower plate 28 respectively have a rectangular shape of the same size when viewed in a normal direction.

The outer periphery portions of the upper plate 26 and the lower plate 28 are provided with edge portions 30 protruding in a thickness direction. The upper plate 26 and the lower plate 28 are integrated and the storage section 24 is formed between the upper plate 26 and the lower plate 28 by joining tips of the edge portions 30 together.

The upper plate 26 and the lower plate 28 are provided with concave sections 26H and 28H at positions to which the air tube 18 is coupleed. Furthermore, the upper plate 26 and the lower plate 28 are provided with concave sections 27H and 29H at positions to which the liquid tube 20 is coupleed.

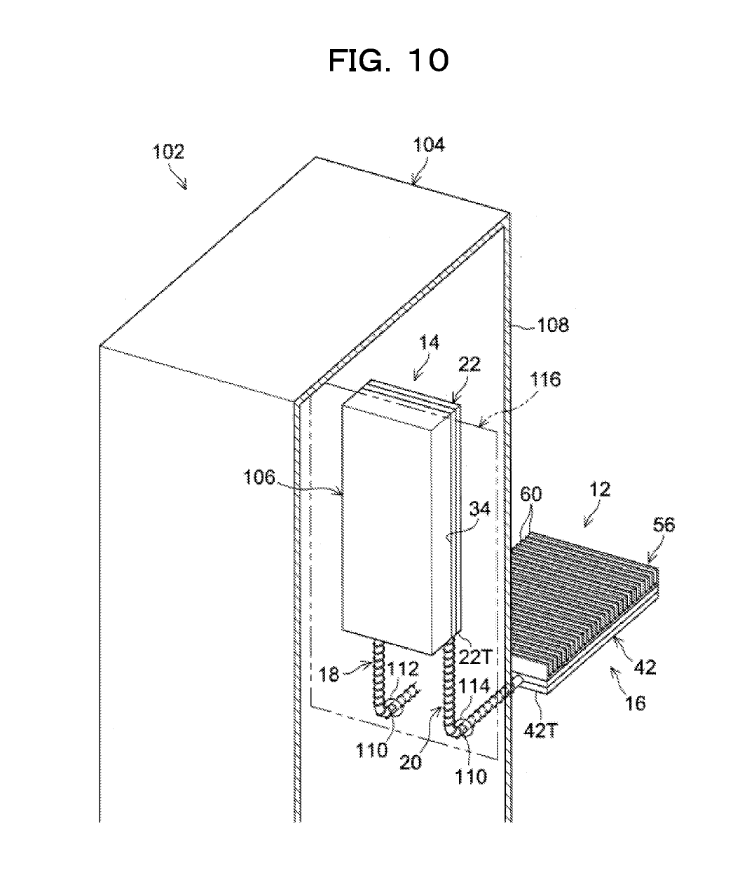

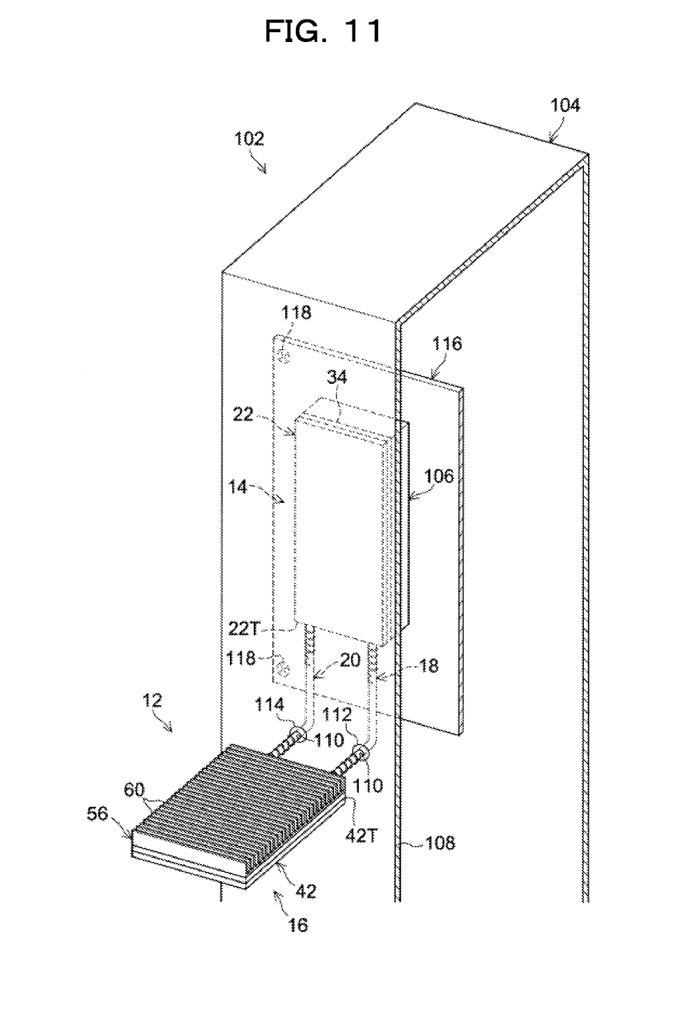

In the heat receiving section 14 of the rectangular parallelepiped shape, one or both of two surfaces having the largest area is a heat receiving surface 34 receiving heat from an electronic component 106 (see FIGS. 10 and 11). In the embodiment, an outer surface of the upper plate 26 is the heat receiving surface 34. The working fluid WF of a liquid phase within the storage section 24 is vaporized by receiving heat by the heat receiving surface 34.

A wick 36 is disposed within the storage section 24 of the heat receiving plate 22. The wick 36 is formed, for example, by knitting filamentous or thin linear metal or resin and exerts a capillary force on the working fluid WF if the wick 36 comes into contact with the working fluid WF of a liquid phase.

As illustrated in FIGS. 2 and 3, in the embodiment, the wick 36 within the storage section 24 is formed in a sheet shape. Then, the wick 36 is disposed at a position close to the heat receiving surface 34 in the storage section 24, that is, is disposed along the upper plate 26. A cavity 38 is provided between the wick 36 and the lower plate 28. As illustrated in FIG. 3, the wick 36 is also disposed within the concave sections 26H and 28H on a side to which the liquid tube 20 is coupleed. Moreover, if both the outer surface of the upper plate 26 and the outer surface of the lower plate 28 are the heat receiving surfaces 34, two sheets of the wicks 36 may respectively come into contact with the upper plate 26 and the lower plate 28, and the cavity 38 may be formed between the two sheets of the wicks 36.

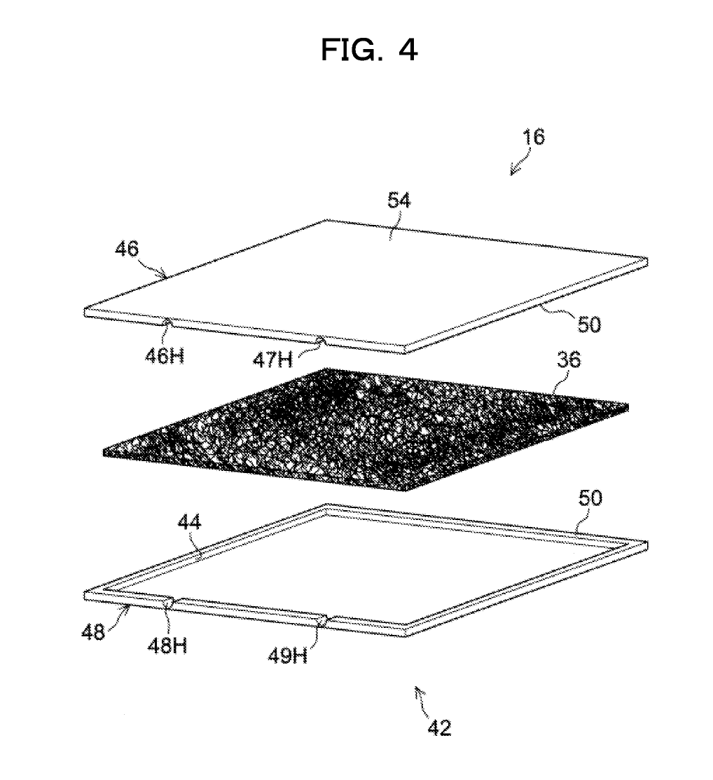

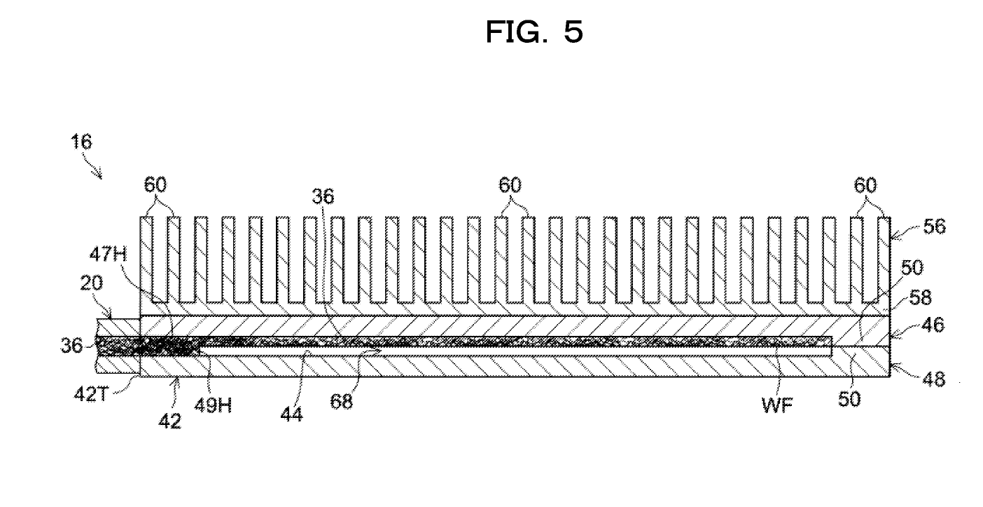

The heat radiation section 16 has a heat radiation plate 42 having a flat rectangular parallelepiped shape. Also as illustrated in FIGS. 4 and 5 in detail, an inside of the heat radiation plate 42 is a hollow storage section 44. The storage section 44 stores a working fluid WF in a sealed state.

The heat radiation plate 42 of the embodiment has an upper plate 46 and a lower plate 48. The upper plate 46 and the lower plate 48 respectively have a rectangular shape of the same size when viewed in a normal direction.

The outer periphery portions of the upper plate 46 and the lower plate 48 are provided with edge portions 50 protruding in a thickness direction. The upper plate 46 and the lower plate 48 are integrated and the storage section 44 is formed between the upper plate 46 and the lower plate 48 by joining tips of the edge portions 50 together.

The upper plate 46 and the lower plate 48 are provided with concave sections 46H and 48H at positions to which the air tube 18 is coupleed. Furthermore, the upper plate 46 and the lower plate 48 are provided with concave sections 47H and 49H at positions to which the liquid tube 20 is coupleed.

In the heat radiation section 16 of the rectangular parallelepiped shape, one or both of two surfaces having the largest area is a heat radiating surface 54. The working fluid WF of a gas phase within the storage section 24 is liquefied by radiating heat from the heat radiating surface 54.

In the embodiment, as illustrated in FIG. 1, a fin member 56 that is an example of a heat radiation element is mounted on the outer surface of the upper plate 46. The fin member 56 has a fin base 58 fixed to the outer surface of the lower plate 48 by coming into contact therewith and a plurality of fin bodies 60 erected from the fin base 58. The heat radiation section 16 has a structure such that heat is efficiently radiated from the heat radiation section 16 by increasing a surface area by the fin bodies 60.

As the heat radiation element, a thermoelectric element such as a Peltier element, a metal block having a large heat capacity, and the like can be exemplified in addition to the fin member 56. The heat radiation element can be mounted on an outer surface of at least one of the upper plate 46 and the lower plate 48.

As illustrated in FIGS. 4, 5, the wick 36 is disposed within the storage section 44 of the heat radiation plate 42. In the embodiment, the wick 36 is disposed at a position close to the fin member 56 in the storage section 44, that is, is disposed along the upper plate 46. A cavity 68 is provided between the wick 36 and the lower plate 48. Moreover, for example, in a structure in which the heat radiation element is also mounted on the outer surface of the lower plate 48, the wick 36 may be disposed along the lower plate 48. In this case, two sheets of the wick 36 may come into contact with both the upper plate 46 and the lower plate 48, and the cavity 68 may be formed between the two sheets of the wick 36.

As illustrated in FIG. 5, the wick 36 is also disposed within the concave sections 47H and 49H on a side to which the liquid tube 20 is coupleed.

As illustrated in FIGS. 1, 6 to 9, both the air tube 18 and the liquid tube 20 are made of metal and are cylindrical tubes having flexibility in a direction intersecting a longitudinal direction. Then, the air tube 18 and the liquid tube 20 couple the heat receiving section 14 and the heat radiation section 16.

As indicated by arrow F1 in FIG. 1, the working fluid WF that is vaporized by the heat receiving section 14, flows through the air tube 18 and moves to the heat radiation section 16. As indicated by arrow F2 in FIG. 1, the working fluid WF liquefied by the heat radiation section 16 flows through the liquid tube 20 and moves to the heat receiving section 14. That is, the heat receiving section 14 and the heat radiation section 16 are coupleed to the air tube 18 and the liquid tube 20, and thereby a circulation flow path in which the working fluid WF circulates is formed.

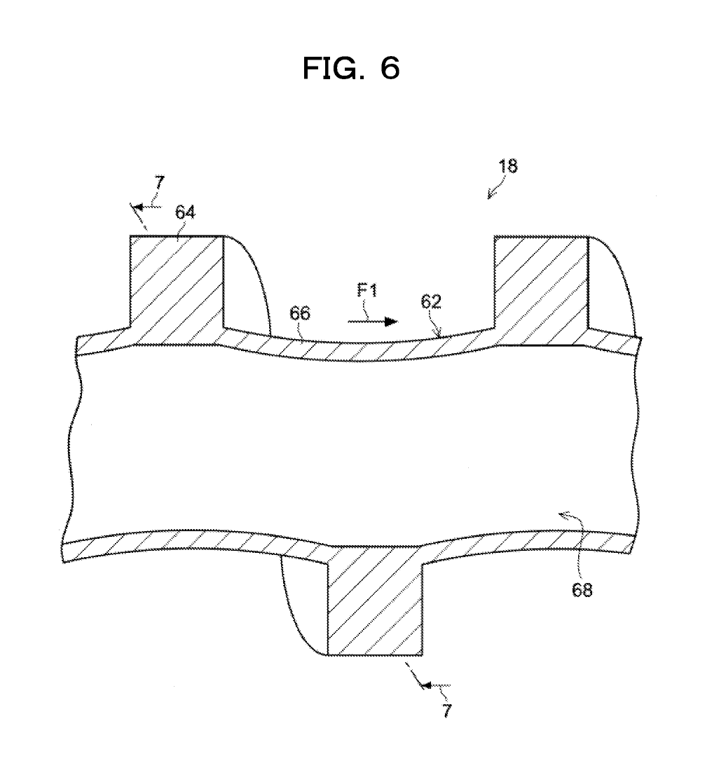

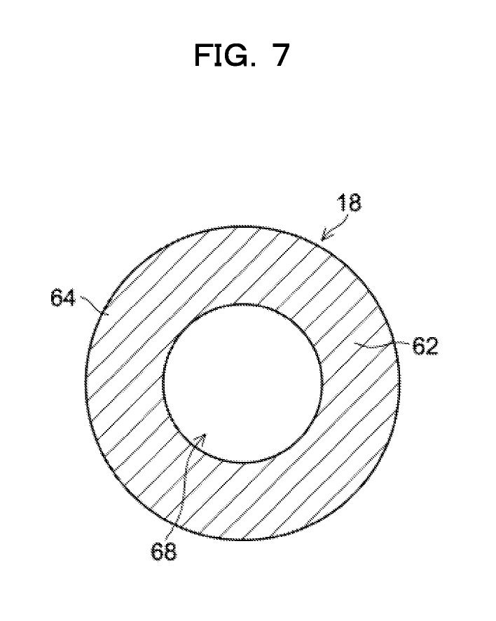

As illustrated in FIGS. 6 and 7, the air tube 18 has a cylindrical tube wall 62 in the longitudinal direction (direction in which the working fluid flows and arrow direction F1). The tube wall 62 is provided with a thick walled section 64 that is a spiral shape and is continuous from one end side to the other end side of the air tube 18. The thick walled section 64 appears repeatedly at certain intervals in the arrow direction F1 when viewed from a cross section illustrated in FIG. 6.

Furthermore, a thin walled section 66 that is continuous from the thick walled section 64 and is thinner than the thick walled section 64 is formed between the thick walled sections 64 when viewed from the cross section illustrated in FIG. 6. The thin walled section 66 is more easily deformed than the thick walled section 64. Then, the air tube 18 expands and contracts along the longitudinal direction by deformation of the thin walled section 66. The air tube 18 has flexibility (flexibility in the direction intersecting the longitudinal direction) capable of bending at a desired position by partially generating the expansion and contraction in the thin walled section 66.

The thick walled section 64 and the thin walled section 66 of the air tube 18 are integrated and a gap is not present between the thick walled section 64 and the thin walled section 66. Thus, the working fluid WF flowing through the inside of the air tube 18 is not leaked to the outside.

The inside of the air tube 18 is the cavity 68.

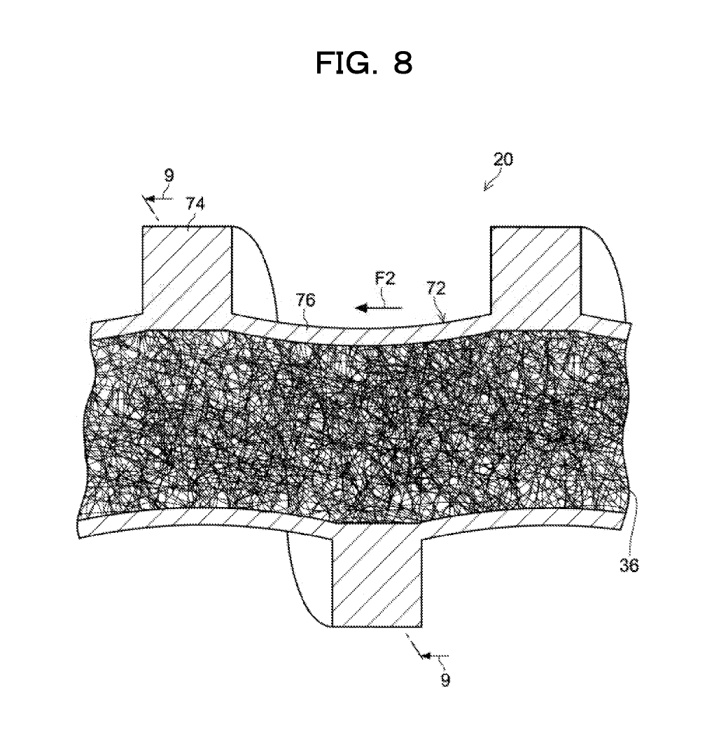

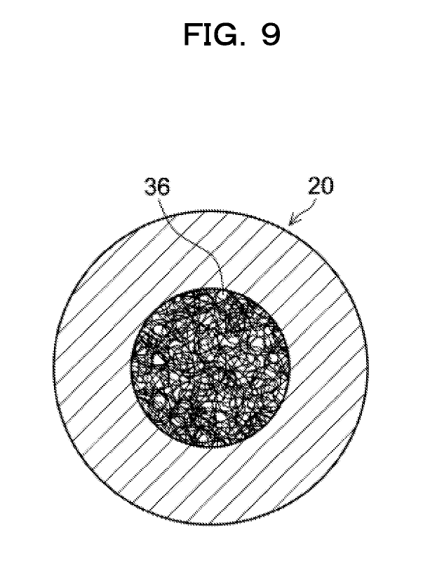

As illustrated in FIGS. 8 and 9, the liquid tube 20 has a cylindrical tube wall 72 in the longitudinal direction (direction in which the working fluid flows and arrow direction F2). The tube wall 72 is provided with a thick walled section 74 that is a spiral shape and is continuous from one end side to the other end side of the liquid tube 20. Similar to the thick walled section 64 of the air tube 18, the thick walled section 74 appears repeatedly at certain intervals in the arrow direction F2 in a cross section illustrated in FIG. 8.

Furthermore, a thin walled section 76 that is continuous from the thick walled section 74 and is thinner than the thick walled section 74 is formed between the thick walled sections 74. The thin walled section 76 is more easily deformed than the thick walled section 74. Then, the liquid tube 20 expands and contracts along the longitudinal direction by deformation of the thin walled section 76. The liquid tube 20 has flexibility (flexibility in the direction intersecting the longitudinal direction) capable of bending at a desired position by partially generating the expansion and contraction in the thin walled section 76.

The thick walled section 74 and the thin walled section 76 of the liquid tube 20 are integrated and a gap is not present between the thick walled section 74 and the thin walled section 76. Thus, the working fluid WF flowing through the inside of the liquid tube 20 is not leaked to the outside.

The inside of the liquid tube 20 is filled with the wick 36. The wick 36 is a member exerting capillary force on the liquid. That is, the wick 36 exerts capillary force on the working fluid WF of the liquid phase within the liquid tube 20 and moves the working fluid WF from the heat radiation section 16 to the heat receiving section 14.

As illustrated in FIG. 3, particularly, the wick 36 within the liquid tube 20 is continuous with the wick 36 within the storage section 24 of the heat receiving section 14 and within the concave sections 27H and 29H. Furthermore, as illustrated in FIG. 5, the wick 36 within the liquid tube 20 is continuous with the wick 36 within the storage section 44 of the heat radiation section 16 and within the concave sections 47H and 49H.

The wick 36 is not specifically limited as long as capillary force can be exerted on the working fluid WF of the liquid phase. For example, if a wick made of glass fiber is used, it is possible to follow bending of the liquid tube 20 and to maintain a state of filling the liquid tube 20. For example, it is possible to use a wick formed of a metal mesh, a metal-powder sintered body, and the like in addition to glass fiber.

As illustrated in FIGS. 1, 10, and 11, the air tube 18 and the liquid tube 20 are coupleed to an end surface 22T of the heat receiving plate 22. The end surface 22T is one of four surfaces other than the two surfaces having the largest area in the heat receiving plate 22.

Furthermore, the air tube 18 and the liquid tube 20 are coupleed to an end surface 42T of the heat radiation plate 42. The end surface 42T is one of four surfaces other than the two surfaces having the largest area in the heat radiation plate 42.

As illustrated in FIGS. 10 and 11, an electronic apparatus 102 has a housing 104. The electronic component 106 is housed and fixed within the housing 104. The electronic component 106 is an example of electronic components.

For example, the housing 104 is formed in a box shape and protects the electronic component 106 from an external environment (weather, a temperature change, a humidity change, and the like) when the electronic apparatus 102 is installed outdoors. As an example of such an electronic apparatus, a base station of a mobile phone may be exemplified. The electronic apparatus 102 may be installed indoors.

A structure fixing the electronic component 106 to the inside of the housing 104 is not limited. In the example illustrated in FIGS. 10 and 11, a substrate 116 is fixed using screws 118 and the like. The electronic component 106 is mounted on the substrate 116.

The heat receiving section 14 of the cooling device 12 is disposed on an inside of the housing 104. On the other hand, the heat radiation section 16 of the cooling device 12 is disposed on an outside of the housing 104. Particularly, in the example illustrated in FIGS. 10 and 11, the heat radiation section 16 is disposed below the heat receiving section 14.

The heat receiving plate 22 is disposed such that the heat receiving surface 34 faces the electronic apparatus 102 or comes into contact with the electronic apparatus 102. Furthermore, the heat receiving plate 22 is disposed such that the end surface 22T to which the air tube 18 and the liquid tube 20 are coupleed faces downward.

The heat radiation plate 42 is disposed such that the fin bodies 60 of the fin member 56 face upward and the end surface 42T to which the air tube 18 and the liquid tube 20 are coupleed faces the housing 104.

A wall portion 108 of the housing 104 is provided with through holes 110. The air tube 18 and the liquid tube 20 are inserted into the through holes 110. In the embodiment, a bushing 112 is disposed between the air tube 18 and the through hole 110 and a bushing 114 is disposed between the liquid tube 20 and the through hole 110.

The bushings 112 and 114 are an example of a sealing member. Specifically, the bushing 112 comes into contact with the outer periphery of the air tube 18 and a hole wall of the through hole 110, and suppresses entering of foreign matter such as liquid including rainwater and dust from a gap between the air tube 18 and the through hole 110 into the housing 104. Similarly, the bushing 114 comes into contact with the outer periphery of the liquid tube 20 and a hole wall of the through hole 110, and suppresses entering of foreign matter such as liquid including rainwater and dust from a gap between the liquid tube 20 and the through hole 110 into the housing 104.

Next, an operation of the embodiment will be described.

As illustrated in FIGS. 1, 10, and 11, in the cooling device 12 of the embodiment, the heat receiving section 14 and the heat radiation section 16 are coupleed by the air tube 18 and the liquid tube 20. Then, in the heat receiving section 14 receiving heat of the electronic component 106, the working fluid WF on the inside thereof is vaporized. The vaporized working fluid WF flows into the heat radiation section 16 via the air tube 18. In the heat radiation section 16, the working fluid WF is liquefied by radiating heat. The liquefied working fluid WF flows into the heat receiving section 14 via the liquid tube 20. Thus, it is possible to continuously perform an operation in which heat of the heat receiving section 14 is transferred to the heat radiation section 16 and heat is radiated by the heat radiation section 16. Since heat of the electronic component 106 is continuously received by the heat receiving section 14, it is possible to cool the electronic component 106.

The air tube 18 and the liquid tube 20 have flexibility in the direction intersecting the longitudinal direction. Thus, the air tube 18 and the liquid tube 20 can be bent at a desired position and a degree of freedom of arrangement of the heat receiving section 14 and the heat radiation section 16 is increased. FIGS. 10 and 11 are an example in which the air tube 18 and the liquid tube 20 have flexibility and thereby the heat receiving section 14 and the heat radiation section 16 are disposed at a desired position and in a desired posture.

Specifically, the heat receiving plate 22 of the heat receiving section 14 is disposed in a vertical direction and the heat radiation plate 42 of the heat radiation section 16 is disposed in a horizontal direction. In addition to this example, the heat receiving section 14 and the heat radiation section 16 may adopt various arrangements. For example, the heat receiving plate 22 may be disposed in the horizontal direction and the heat radiation plate 42 may be disposed in the vertical direction. Furthermore, one or both of the heat receiving plate 22 and the heat radiation plate 42 may be disposed to be inclined.

Particularly, various components in addition to the electronic component 106 may be disposed on the inside of the housing 104. Then, it is preferable that heat is efficiently received from the electronic component 106 by the heat receiving section 14 (heat receiving plate 22) while avoiding those components. In the embodiment, since the degree of freedom of the arrangement of the heat receiving section 14 is increased, other components are avoided and the position and the posture of the heat receiving plate 22 capable of efficiently receiving heat from the electronic component 106 may be taken.

For example, there may be a building wall, various external cables, and the like (collectively referred to as “external member”) on the outside of the housing 104 depending on a location in which the electronic apparatus 102 is disposed. Then it is preferable that heat is efficiently radiated by the heat radiation section 16 (heat radiation plate 42) while avoiding the external member. In the embodiment, since the degree of freedom of the arrangement of the heat radiation section 16 is increased, the external member is avoided and the position and the posture of the heat radiation section 16 capable of efficiently radiating heat may be taken.

Furthermore, when assembling the cooling device 12 to the housing 104, the degree of freedom of the arrangement of the heat receiving section 14 and the heat radiation section 16 is also increased. That is, since the positions of the heat receiving section 14 and the heat radiation section 16 are not fixed, assembly work is easy.

Then, a degree of freedom of a relative position between the heat receiving section 14 and the heat radiation section 16 is also increased. For example, in the example illustrated in FIGS. 10 and 11, the heat radiation section 16 is positioned on a lower side further than the heat receiving section 14. As described above, the heat radiation section 16 may be disposed on the lower side further than the heat receiving section 14 and the degree of freedom of the arrangement of the heat radiation section 16 is increased.

The working fluid WF flows through the insides of the air tube 18 and the liquid tube 20. Since the air tube 18 and the liquid tube 20 are made of metal, for example, coming out of the working fluid WF is suppressed compared to a case where the air tube and the liquid tube are made of resin. Since the working fluid WF can be maintained in a state of being sealed on the inside of the cooling device 12, it is possible to maintain cooling performance of the cooling device 12 over a long period of time.

Moreover, as the structure having flexibility described above in the air tube 18 and the liquid tube 20, in the embodiment, a structure in which the tube walls 62 and 72 have the thick walled sections 64 and 74, and the thin walled sections 66 and 76 is exemplified. In order to impart flexibility to the air tube 18 and the liquid tube 20, for example, a structure having only the thin walled sections 66 and 76 may be provided. However, in a structure not having the thick walled sections 64 and 74, it is difficult to stably maintain the air tube 18 and the liquid tube 20 in desired shapes. That is, as the air tube 18 and the liquid tube 20, it is possible to achieve both flexibility and shape stability by providing the structure having both the thick walled sections 64 and 74, and the thin walled sections 66 and 76.

Furthermore, as illustrated in FIGS. 6 and 8, the thin walled sections 66 and 76 are continuous to the thick walled sections 64 and 74. Since a gap is not present between the thick walled sections 64 and 74, and the thin walled sections 66 and 76, it is possible to suppress leakage of the working fluid from the gap.

However, a structure in which the thick walled sections 64 and 74, and the thin walled sections 66 and 76 are not completely integrated is applicable. For example, first, the thick walled sections of the spiral shape are formed, a portion between the thick walled sections is coupleed by the thin walled section in a later step, and then it is possible to obtain the cylindrical air tube 18 and liquid tube 20 as a whole.

In the embodiment, as illustrated in FIGS. 10 and 11, if the heat radiation section 16 is disposed on the lower side further than the heat receiving section 14, in a vertical portion of the liquid tube 20, gravity acts in a direction opposite to a direction in which the working fluid WF liquefied by the heat radiation section 16 returns to the heat receiving section 14.

In the embodiment, the liquid tube 20 is filled with the wick 36. The wick 36 exerts capillary force on the liquid. Thus, even if gravity acts on the working fluid WF in the direction opposite to the direction in which the working fluid WF returns from the heat radiation section 16 to the heat receiving section 14, it is possible to return the working fluid WF from the heat radiation section 16 to the heat receiving section 14 by decreasing the influence of gravity.

For example, if the end surface 42T of the heat radiation plate 42 faces upward, a part of the liquid tube 20 on the heat radiation plate 42 side has a posture extending upward from the heat radiation plate 42. The working fluid WF of the liquid phase moving from the heat radiation section 16 to the heat receiving section 14 receives gravity in a direction opposite to the moving direction in an initial step of the movement. Even in this case, since the wick 36 within the liquid tube 20 exerts capillary force on the working fluid WF of the liquid phase, it is possible to move the working fluid WF to the heat radiation section 16. That is, it is possible to make the working fluid WF flow into the liquid tube 20 regardless of the orientation or the posture of the heat radiation section 16.

Moreover, the air tube 18 is not filled with the wick 36 and the cavity 68 is present within the air tube 18. Thus, a pressure loss in the air tube 18 is greater than that in the liquid tube 20. In other words, resistance in the liquid tube 20 when the fluid flows through the inside thereof is greater than that in the air tube 18. Thus, the vaporized working fluid WF within the heat receiving section 14 is likely to flow through the air tube 18 but is unlikely to flow through the liquid tube 20. That is, it is possible to realize a one-way circulation flow path in which the working fluid WF (gas) from the heat receiving section 14 to the heat radiation section 16 flows through the air tube 18 and the working fluid WF (liquid) from the heat radiation section 16 to the heat receiving section 14 flows through the liquid tube 20.

As illustrated in FIGS. 2 and 3, the wick 36 is disposed within the storage section 24 of the heat receiving section 14. Diffusion of the working fluid WF of the liquid phase is promoted by the wick 36 within the storage section 24. Thus, it is possible to efficiently operate heat to the working fluid WF and to vaporize the working fluid WF within the storage section 24.

Particularly, the wick 36 is disposed along the upper plate 26. That is, since the wick 36 is disposed to be spread at a position close to the heat receiving surface 34 in the storage section 24, it is possible to diffuse the working fluid WF along the heat receiving surface 34. Since heat is received in a wide surface by the diffused working fluid WF, it is possible to efficiently vaporize the working fluid WF.

As illustrated in FIGS. 4 and 5, the wick 36 is disposed within the storage section 44 of the heat radiation section 16. In the structure in which the wick 36 is not disposed within the storage section 44, the working fluid WF only comes into contact with the wall surface of the storage section 44, but in the structure in which the wick 36 is disposed, since the working fluid WF also comes into contact with the wick 36, the contact surface of the working fluid WF is increased. That is, since the area for cooling the working fluid WF by depriving heat from the working fluid WF is increased, it is possible to efficiently cool the working fluid WF in a shorter amount of time and to move the working fluid WF within the liquid tube 20.

Particularly, it is possible to employ a structure in which the wick 36 within the liquid tube 20 is continuous to the wick 36 within the storage section 44 and the wick within the storage section 24. Thus, the working fluid WF liquefied within the storage section 44 smoothly moves to the wick 36 within the liquid tube 20 and moves to the wick 36 within the storage section 24. That is, the working fluid WF within the storage section 44 smoothly moves within the storage section 24.

In the embodiment, as illustrated in FIGS. 10 and 11, the housing 104 is provided. Even if the electronic apparatus does not have the housing 104, it is possible to cool the electronic component 106 by the cooling device 12, but it is possible to protect the electronic component 106 from the external environment by disposing the electronic component 106 within the housing 104. Particularly, if the electronic apparatus 102 is installed outdoors, it is possible to protect the electronic component 106 from the weather, the temperature, and the humidity of the external environment. Then, since the heat receiving section 14 is disposed on the inside of the housing 104, it is possible to efficiently receive heat from the electronic component 106 within the housing 104. Since the heat radiation section 16 is disposed on the outside of the housing 104, it is possible to efficiently radiate heat by taking an outside temperature. Then, the air tube 18 and the liquid tube 20 pass through the through hole 110 of the housing 104 and thereby it is possible to easily realize the structure in which the heat receiving section 14 is disposed on the inside of the housing 104 and the heat radiation section 16 is disposed on the outside of the housing 104.

Furthermore, as illustrated in FIGS. 10 and 11, the bushings 112 and 114 are disposed between the through hole 110 of the wall portion 108 of the housing 104, the air tube 18, and the liquid tube 20. It is possible to suppress entering of foreign matter such as liquid including rainwater and dust from the gap between the air tube 18 and the through hole 110, and the gap between the liquid tube 20 and the through hole 110 into the housing 104 by the bushings 112 and 114.

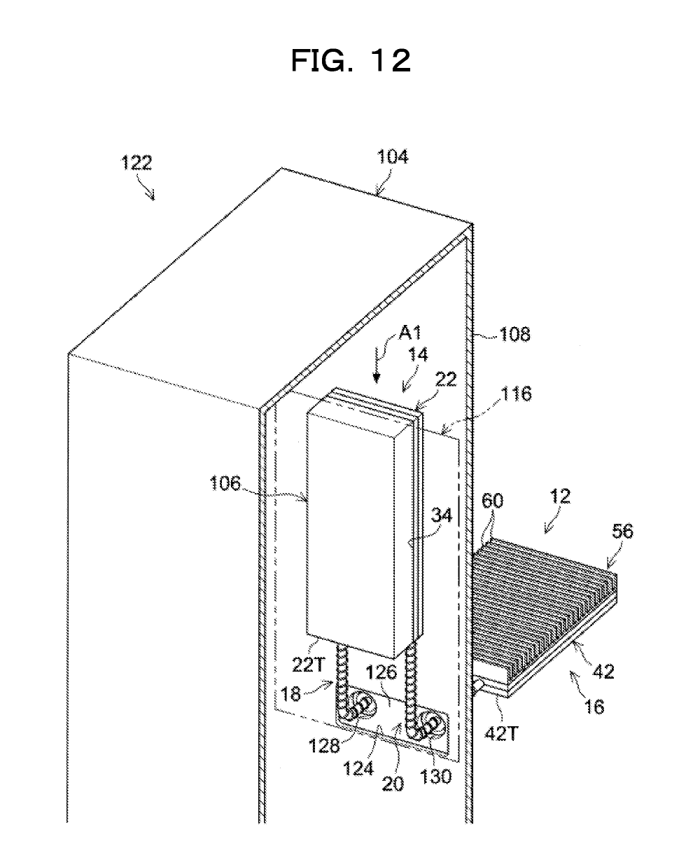

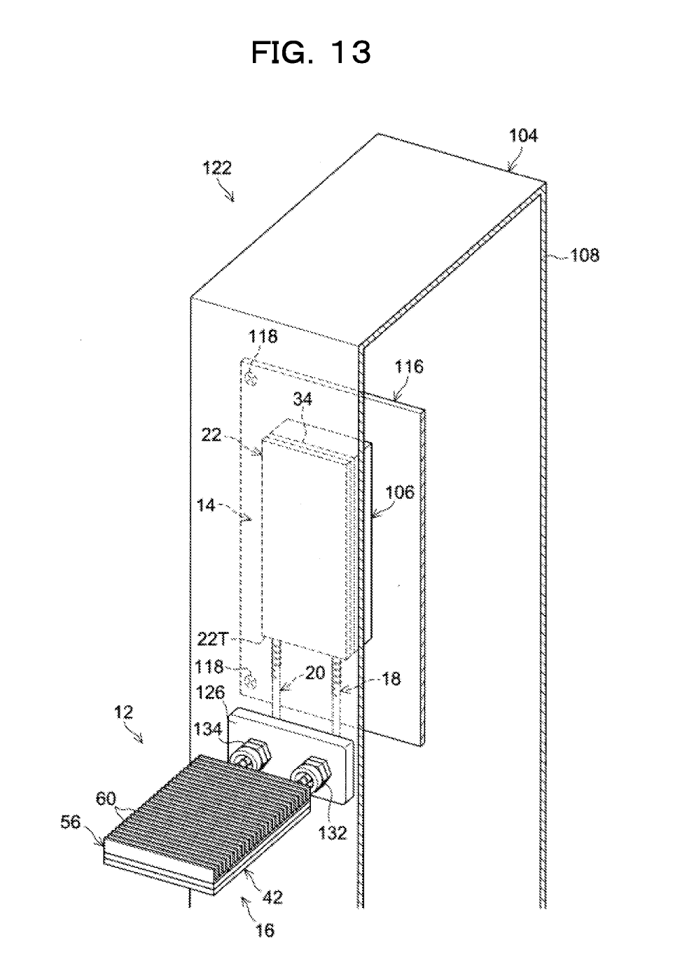

Moreover, it is possible to employ a structure illustrated in FIGS. 12 and 13 that is a second embodiment instead of the bushing 112. In the second embodiment, since a structure of the cooling device 12 is the same as the first embodiment, detailed description will be omitted.

In an electronic apparatus 122 of the second embodiment, a through hole 124 is formed in a wall portion 108 of a housing 104. The through hole 124 is greater than an outer shape of a heat receiving plate 22 when viewed the heat receiving plate 22 in an arrow direction Al. The arrow direction Al is the same direction as a direction in which an air tube 18 and a liquid tube 20 exit from an end surface 22T of the heat receiving plate 22. Then, it is possible to insert the heat receiving plate 22 from the outside to the inside of the housing 104 in a direction opposite to the arrow direction Al.

A lid plate 126 is mounted on the housing 104 from the outside of the housing 104. The through hole 124 is closed by lid plate 126.

Through holes 128 and 130 through which the air tube 18 and the liquid tube 20 pass respectively are formed in lid plate 126. Then, coupleors 132 and 134 are disposed between the air tube 18 and the liquid tube 20, and the through holes 128 and 130.

Lid plate 126 and the coupleors 132 and 134 are an example of a sealing member. Lid plate 126 and the coupleor 132 suppress entering of foreign matters such as the liquid including rainwater and dust from a portion between the air tube 18 and the through hole 124 into the housing 104. Similarly, lid plate 126 and the coupleor 132 suppress entering of the foreign matters such as the liquid including rainwater and dust from a portion between the liquid tube 20 and the through hole 124 into the housing 104.

In the second embodiment, for example, in a state where lid plate 126 is mounted through the coupleors 132 and 134 in the middle of the air tube 18 and the liquid tube 20, it is possible to make the heat receiving section 14 pass through the through hole 124 from the outside of the housing 104 and to dispose the heat receiving section 14 within the housing 104. The lid plate 126 is fixed to the wall portion 108 so as to block the through hole 124.

As described above, the second embodiment has the structure in which the heat receiving plate 22 can pass through the through hole 124. Thus, it is possible to form the cooling device 12 by assembling the heat receiving section 14, the heat radiation section 16, the air tube 18, and the liquid tube 20 in advance, to dispose the heat receiving section 14 of the cooling device 12 within the housing 104 through the through hole 124, and to easily perform assembling work of the cooling device 12 to the housing.

Furthermore, it is possible to suppress entering of the foreign matters such as the liquid including rainwater and dust from the outside of the housing 104 into the housing 104 with a simple structure in which the coupleors 132 and 134 are mounted on lid plate 126.

Next, a third embodiment will be described. In the third embodiment, the same reference numerals are given to the same elements, members, and the like as the first embodiment and detailed description will be omitted.

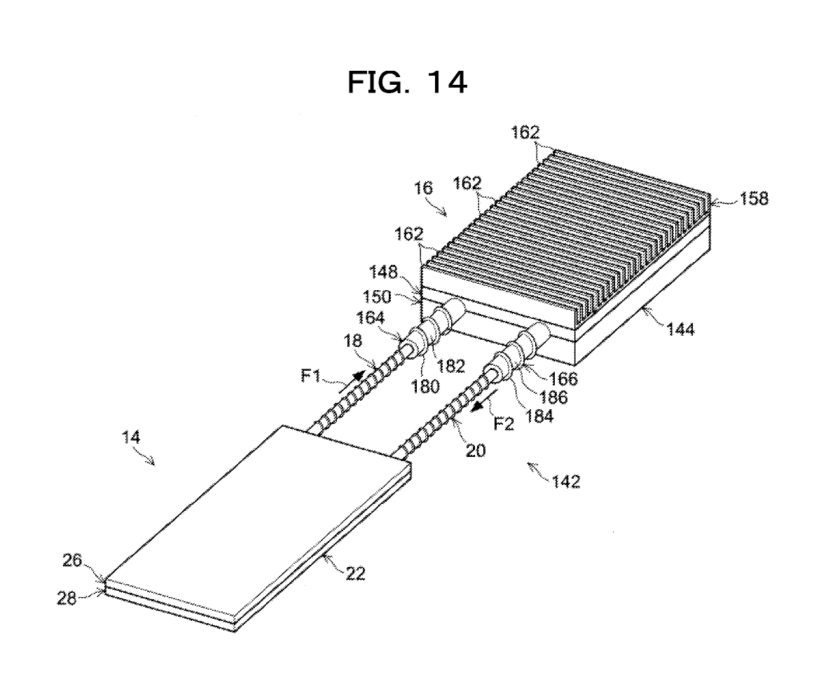

As illustrated in FIGS. 14 to 17, a cooling device 142 of the third embodiment has a metal case 144. A storage section 146 is formed on an inside of the case 144. The case 144 stores a heat radiation section 16 in a storage section 146 and is formed in a rectangular parallelepiped shape having an inner dimensions capable of covering an entirety of the heat radiation section 16. For example, the heat radiation section 16 may employ a structure in which a heat radiation member such as the fin member 56 is mounted on the heat radiation plate 42 (see FIG. 1), but in this case, the case 144 covers the entirety of the heat radiation section 16 including the heat radiation member.

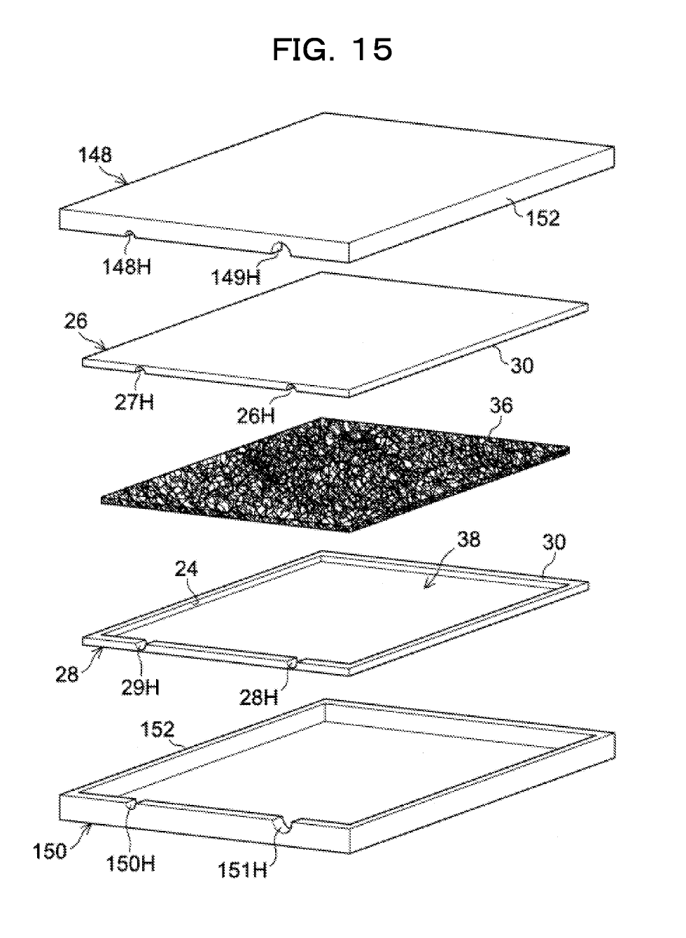

The case 144 has an upper plate 148 and a lower plate 150. As illustrated in FIG. 15, the outer peripheral portions of the upper plate 148 and the lower plate 150 are provided with edge portions 152 protruding in a thickness direction. The upper plate 148 and the lower plate 150 are integrated and the storage section 146 is formed between the upper plate 148 and the lower plate 150 by joining tips of the edge portions 152 together.

The upper plate 148 and the lower plate 150 are provided with concave sections 148H and 150H at positions through which the air tube 18 passes. Furthermore, the upper plate 148 and the lower plate 150 are provided with concave sections 149H and 151H at positions in which a liquid tube cover 166 is disposed.

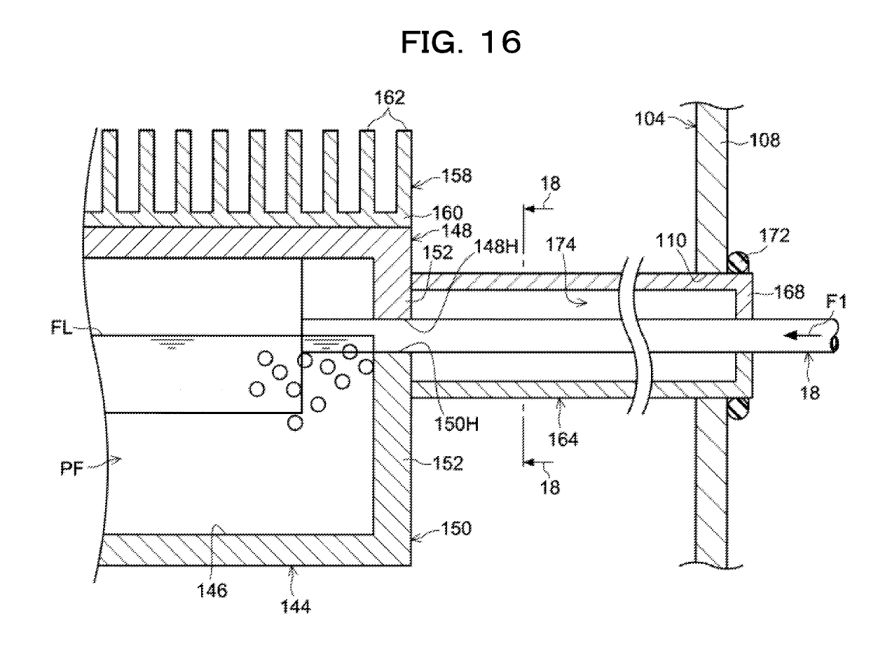

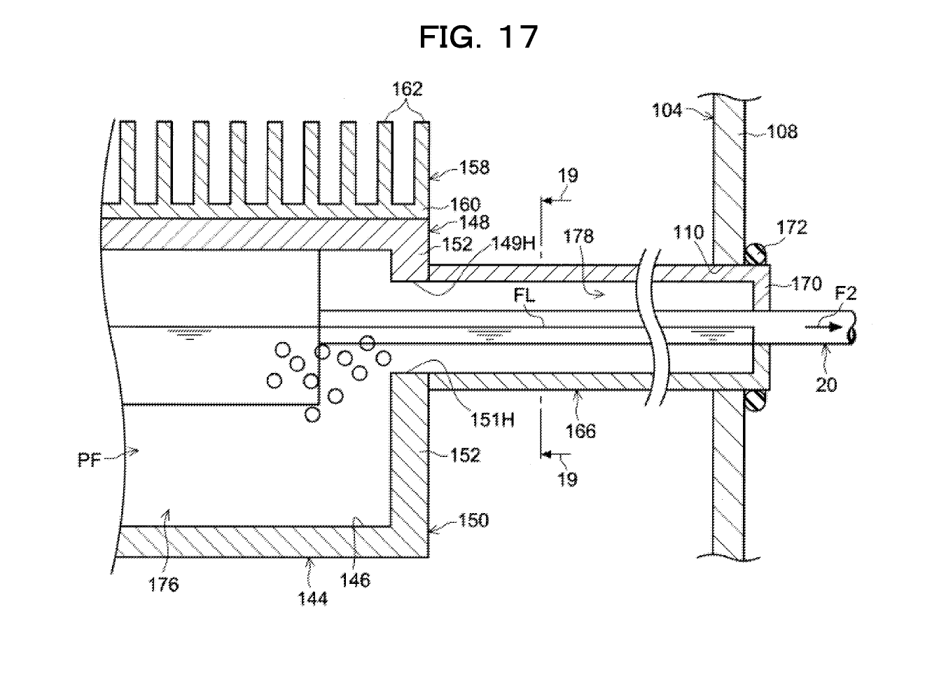

A fin member 158 is mounted on an outer surface of the upper plate 148 of the case 144. In the example illustrated in FIGS. 16 and 17, the fin member 158 has a structure having a fin base 160 that comes into contact with and is fixed to the upper plate 148 and a plurality of fin bodies 162 erected from the fin base 160. Heat radiation is promoted by the fin member 158 from the case 144. Moreover, as a member for promoting heat radiation from the case 144, it is possible to use a thermoelectric element such as a Peltier element, a metal block having a large heat capacity, and the like instead of the fin member 158. The member for promoting heat radiation from the case 144 can be mounted on at least one side of the upper plate 148 and the lower plate 150.

Furthermore, in the third embodiment, as illustrated in FIG. 14, an air tube cover 164 and the liquid tube cover 166, which respectively cover portions on the heat radiation section 16 side, are provided in the air tube 18 and the liquid tube 20.

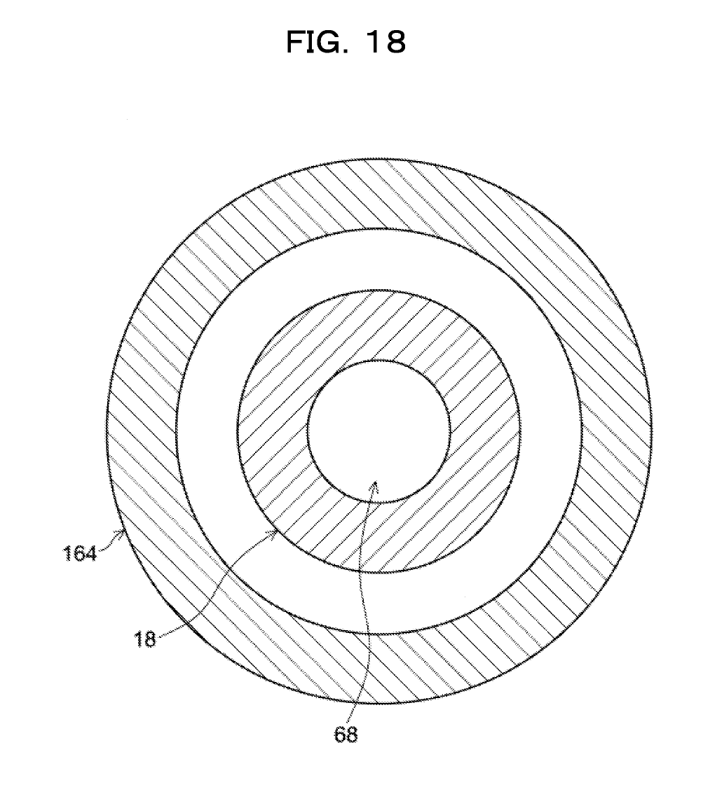

As illustrated in FIG. 18, the air tube cover 164 is a member that is made of metal and is cylindrical, and covers an entire periphery around the air tube 18 having a space 174 between the air tube cover 164 and the air tube 18.

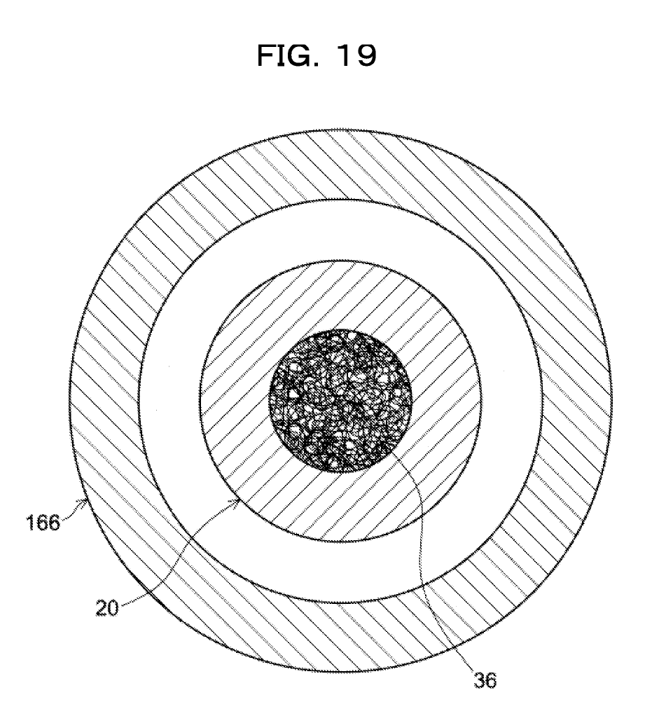

As illustrated in FIG. 19, the liquid tube cover 166 is a member that is made of metal and is cylindrical, and covers an entire periphery around the liquid tube 20 having a space 178 between the liquid tube cover 166 and the liquid tube 20.

As illustrated in FIG. 17, the portion in which the air tube cover 164 covers the air tube 18 is a portion positioned on an outside (left side in FIG. 17) of the housing 104 in a state where the cooling device 142 is mounted on the housing 104.

A tip of the air tube cover 164 passes through the through hole 110 of the housing 104 and is positioned on the inside (right side of the wall portion 108 in FIG. 16) of the housing 104. Then, the tip of the air tube cover 164 is closed by a closing plate 168.

A sealing member 172 seals between an outer periphery of the air tube cover 164 and the through hole 110 within the housing 104. As an example of the sealing member 172, an annular packing and the like can be exemplified.

A base end (end portion on the case 144 side) of the air tube cover 164 is sealed by the case 144. Air is sealed on an inside of the air tube cover 164, that is, a space 174 between the air tube cover 164 and the air tube 18.

As illustrated in FIG. 16, a portion in which the liquid tube cover 166 covers a liquid tube 20 is a portion positioned on the outside of the housing 104 in the state where the cooling device 142 is mounted on the housing 104.

A tip of the liquid tube cover 166 passes through the through hole 110 of the housing 104 and is positioned on the inside (right side of the wall portion 108 in FIG. 17) of the housing 104. Then, the tip of the liquid tube cover 166 is closed by a closing plate 170.

The sealing member 172 seals between the outer periphery of the liquid tube cover 166 and the through hole 110.

In a base end (end portion on the case 144 side) of the liquid tube cover 166, a gap is generated between the concave sections 149H and 151H, and the liquid tube 20. The inside of the liquid tube cover 166, that is, a space 178 between the liquid tube cover 166 and the liquid tube 20 is communicates with a space 176 on an inside of the case 144.

Moreover, in FIGS. 16 and 17, the thick walled section 64 and the thin walled section 66 of the air tube 18 and the liquid tube 20 are not illustrated, but as illustrated in FIGS. 6 and 8, in fact, it is a structure in which the thick walled sections 64 and 74, and the thin walled sections 66 and 76 are formed.

Furthermore, in the third embodiment, as illustrated in FIG. 14, it is a structure in which a thick walled section 180 and a thin walled section 182 are formed in the air tube cover 164, and which has flexibility. Thus, the air tube cover 164 is also deformed together with the air tube 18.

Similarly, it is a structure in which a thick walled section 184 and a thin walled section 186 are formed in the liquid tube cover 166, and which has flexibility. Thus, the liquid tube cover 166 is also deformed together with the liquid tube 20.

As illustrated in FIGS. 16 and 17, a phase-change fluid PF is enclosed in the spaces 176 and 178. A phase change of the phase-change fluid PF is performed from liquid to gas by heat received from the heat radiation section 16 and the phase-change fluid PF is a fluid changing the phase from gas to liquid by radiating heat to the case 144. The phase-change fluid PF may be the same type as the working fluid WF which is enclosed in the heat receiving section 14, the heat radiation section 16, the air tube 18, and the liquid tube 20 or may be a different type therefrom.

In the third embodiment, as described above, the heat radiation section 16 is covered by the case 144. If the heat radiation section 16 is disposed on the outside of the housing 104, it is possible to efficiently radiate heat by taking the outside temperature, but the heat radiation section 16 is exposed to the external environment. On the other hand, if the heat radiation section 16 is covered by the case 144, even if the heat radiation section 16 is disposed on the outside of the housing 104, it is possible to suppress corrosion and damage of the heat radiation section 16 over a long period of time. In other words, it is possible to dispose the heat radiation section 16 on the outside of the housing 104 and to efficiently radiate heat from the heat radiation section 16 to the external air by suppressing corrosion and damage of the heat radiation section 16.

Furthermore, in the third embodiment, a part (portion on the heat radiation section 16 side) of the air tube 18 is covered by the air tube cover 164. If the heat radiation section 16 is disposed on the outside of the housing 104, a part of the air tube 18 is also positioned on the outside of the housing 104. As described above, even if a part of the air tube 18 is positioned on the outside of the housing 104, it is possible to suppress corrosion and damage of the air tube 18 over a long period of time.

Furthermore, in the third embodiment, a part (portion on the heat radiation section 16 side) of the liquid tube 20 is covered by the liquid tube cover 166. If the heat radiation section 16 is disposed on the outside of the housing 104, a part of the liquid tube 20 is also positioned on the outside of the housing 104. As described above, even if a part of the liquid tube 20 is positioned on the outside of the housing 104, it is possible to suppress corrosion and damage of the liquid tube 20 over a long period of time.

In the third embodiment, the phase-change fluid PF is enclosed in the space 176. Thus, the phase-change fluid PF is vaporized by heat of the heat radiation section 16. Thus, it is possible to promote heat radiation from the heat radiation section 16 compared to a structure the phase-change fluid PF is not present in the space 176.

In the third embodiment, the phase-change fluid PF is enclosed in the space 178. Thus, the phase-change fluid PF is vaporized by heat of the liquid tube 20. Thus, it is possible to promote heat radiation from the liquid tube 20 compared to a structure the phase-change fluid PF is not present in the space 178.

Furthermore, in the third embodiment, as illustrated in FIG. 17, if some of the phase-change fluid PF is vaporized in the space 176, a pressure of gas portion is increased in the space 176 and a liquid surface FL is pushed down. The phase-change fluid PF of the gas phase flows into the space 178, heat is radiated from the surface of the liquid tube cover 166, and the phase-change fluid PF is liquefied. That is, in the third embodiment, it is possible to efficiently cool the working fluid WF within the heat radiation section 16 and the liquid tube 20 by generating the phase change also in the phase-change fluid PF within the space 178. For example, it is possible to cool the working fluid WF within the liquid tube 20 to the position of the tip (closing plate 170) of the liquid tube cover 166.

Particularly, since the liquid tube cover 166 has the thick walled section 184 and the thin walled section 186, for example, a surface area is wide compared to a structure which does not have the thick walled section 184. In other words, the thick walled section 184 functions as the radiation fin and it is possible to efficiently radiate heat with a wide area.

Materials of the case 144, the air tube cover 164, and the liquid tube cover 166 are not specifically limited from the viewpoint of suppressing corrosion or damage of the heat radiation section 16, the air tube 18, and the liquid tube 20.

However, as described above, in the structure in which the phase-change fluid PF is enclosed on the inside of the case 144 and the inside of the liquid tube cover 166, if the case 144 and the liquid tube cover 166 are made of metal, it is possible to suppress coming out of the phase-change fluid PF.

In this case, if metal is aluminum or aluminum alloy, it is possible to achieve both light weight and corrosion resistance. Particularly, in a case of aluminum alloy of MS symbol A6063, it is possible to suppress damage due to rust and the like, and to maintain the structure of the case 144 and the liquid tube cover 166 over a long period of time.

In the third embodiment, as described above, the portion positioned on the outside of the housing 104 is covered by the case 144, the air tube cover 164, and the liquid tube cover 166, and thereby corrosion is suppressed. Thus, for the heat radiation section 16, the air tube 18, and the liquid tube 20, it is possible to use a material having a low corrosion resistance if the heat radiation section 16, the air tube 18, and the liquid tube 20 are exposed to the external air, for example, to use copper and the like.

As illustrated in FIG. 16, since a base end portion of the air tube cover 164 is sealed by the case 144, the phase-change fluid PF does not flows into the space 174 and a state where air is enclosed in the space 174 is maintained. Heat radiation from the working fluid (gas) within the air tube 18 is suppressed by thermal insulation action of air of the space 174. Thus, since it is possible to highly maintain a temperature difference in the working fluid on the insides of the air tube 18 and the liquid tube 20 by the air tube 18 and the liquid tube 20, as the cooling device 142, efficiency of heat transport increases.

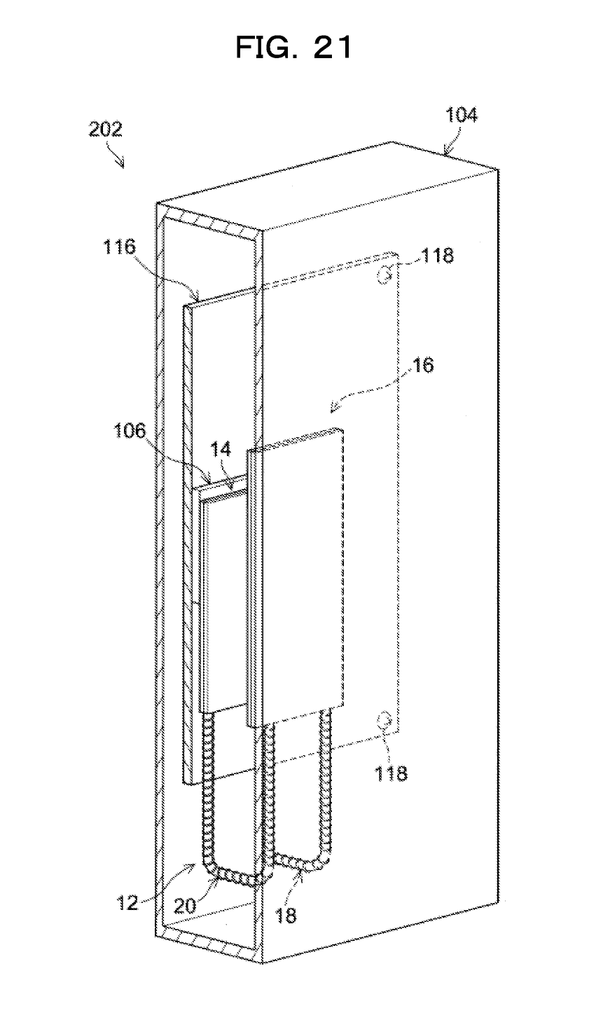

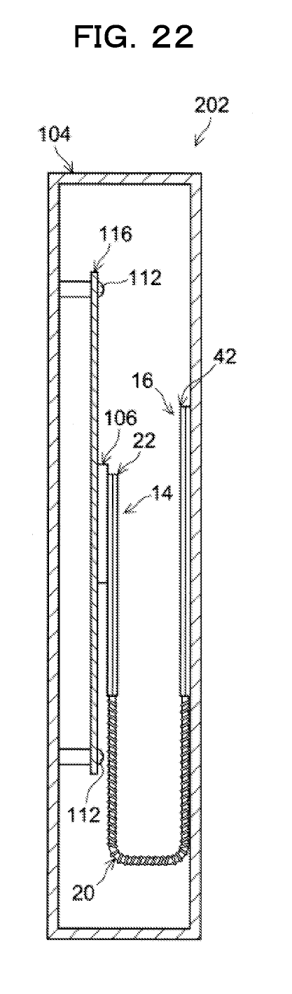

Next, a fourth embodiment will be described. In the fourth embodiment, the same reference numerals are given to the same elements, members, and the like as the first embodiment and detailed description will be omitted. Moreover, as the cooling device, an example using the cooling device 12 of the first embodiment is illustrated in FIGS. 21 and 22.

In the electronic apparatus 202 of the fourth embodiment, as illustrated in FIGS. 21 and 22, a heat radiation section 16 is disposed an inside of a housing 104. Particularly, in the example of FIGS. 21 and 22, a heat radiation plate 42 is disposed parallel to a heat receiving plate 22. Since an air tube 18 and a liquid tube 20 have flexibility, as described above, it is easy to dispose the heat receiving plate 22 and the heat radiation plate 42 in parallel by bending the air tube 18 and the liquid tube 20 in a substantially U shape. For example, if a space, in which the heat radiation section 16 is disposed on an outside of the housing 104, is not present, the heat receiving plate 22 and the heat radiation plate 42 may be disposed within the housing 104 in parallel.

In the fourth embodiment, in the example illustrated in FIG. 22, the heat radiation plate 42 comes into contact with a wall surface of the housing 104. Thus, the housing 104 is used as a heat radiation element and it is possible to promote heat radiation from the heat radiation plate 42.

Next, a fifth embodiment will be described. In the fifth embodiment, the same reference numerals are given to the same elements, members, and the like as the first embodiment and detailed description will be omitted. Moreover, in the fifth embodiment, as the electronic apparatus, since the same structure as the electronic apparatus 102 (see FIGS. 10 and 11) of the first embodiment, the electronic apparatus 122 (see FIGS. 12 and 13) of the second embodiment, and the electronic apparatus 202 (see FIGS. 21 and 22) of the fourth embodiment may be employed, illustration is omitted.

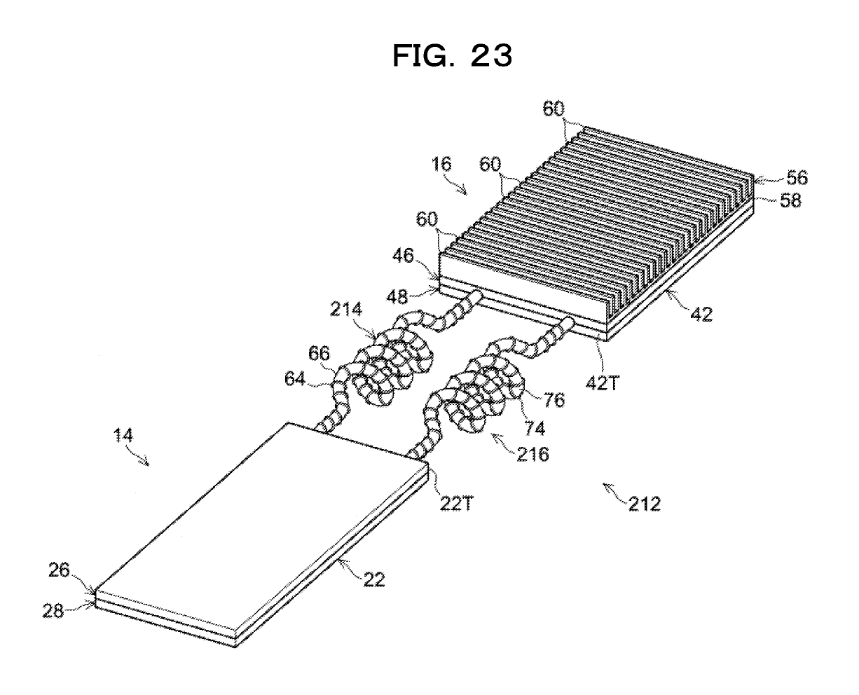

As illustrated in FIG. 23, in a cooling device 212 of the fifth embodiment, an air tube 214 has a thick walled section 64 and a thin walled section 66 of a tube wall 62, and the air tube 214 is formed in a spiral shape as a whole. Similarly a liquid tube 216 has a thick walled section 74 and a thin walled section 76 of a tube wall 62, and the liquid tube 20 is formed in a spiral shape as a whole.

As described above, if the air tube 214 and the liquid tube 216 are formed in the spiral shape as a whole, not only deformation according to expansion and contraction of the thin walled section 66 but also deformation according to deflection as an entire tube is generated. However, in the fifth embodiment, since the air tube and the liquid tube are long compared to those of the first embodiment to the fourth embodiment, pressure loss is increased. Furthermore, a wide space is occupied as much as the air tube and the liquid tube are formed in the spiral shape as a whole. On the other hand, in the first embodiment to the fourth embodiment, it is possible to suppress the pressure an increase in loss of the air tube and the liquid tube, and to narrow the space occupied by the air tube and the liquid tube.

In the above description, as the heat receiving section 14, a structure having the heat receiving plate 22 formed in a plate shape is exemplified. As the heat receiving section, a shape other than the plate shape may be provided. However, if it is the plate shape, it is possible to easily realize the structure having a wide surface (heat receiving surface 34) receiving heat by coming into contact with the electronic component 106.

Furthermore, the inside of the heat receiving plate 22 is hollow and thereby it is possible to ensure the space for enclosing the working fluid WF with a simple structure.

In the heat receiving plate 22, the air tube 18 and the liquid tube 20 are coupleed to an end surface 22T of the heat receiving plate 22. Since the air tube 18 and the liquid tube 20 avoid a wide surface in the heat receiving plate 22, it is possible to efficiently use the wide surface as the heat receiving surface 34 and to make the wide surface come into contact with the electronic component 106. For example, two wide surfaces are present in the heat receiving plate 22 and it is also possible to employ a structure in which heat of the electronic component is received by the two surfaces.

Similarly, in the above description, as the heat radiation section 16, a structure having the heat radiation plate 42 formed in the plate shape is exemplified. As the heat radiation section 16, shapes other than the plate shape may be provided, but if the heat radiation section 16 has the plate shape, the surface area is large compared to a volume and it is possible to easily realize a structure that is advantageous in heat radiation.

Furthermore, the inside of the heat radiation plate 42 is hollow and thereby it is possible to ensure the space for enclosing the working fluid WF with a simple structure.

In the heat radiation plate 42, the air tube 18 and the liquid tube 20 are coupleed to an end surface 42T of the heat radiation plate 42. Since the air tube 18 and the liquid tube 20 avoid a wide surface in the heat radiation plate 42, when mounting the heat radiation element (for example, the fin member 56 illustrated in FIG. 1) on the wide surface, it is possible to easily realize a structure having high heat radiation efficiency without disturbing of the air tube 18 and the liquid tube 20.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A cooling device comprising:
a heat receiver in which a working fluid is enclosed;
a heat sink in which the working fluid is enclosed;
an air tube made of metal so as to have flexibility, the air tube coupling the heat receiver and the heat sink, the air tube in which the working fluid of a gas phase flows through; and
a liquid tube made of metal so as to have flexibility, the liquid tube coupling the heat receiver and the heat sink, the liquid tube in which the working fluid of a liquid phase flows through.

2. The cooling device according to claim 1, wherein
walls of the air tube and the liquid tube include a thick wall formed in a spiral shape and a thin wall which is thinner than the thick wall and continuous from the thick wall so as not to leak the working fluid.

3. The cooling device according to claim 1, wherein
the liquid tube is filled with a wick exerting a capillary force to the working fluid.

4. The cooling device according to claim 3, wherein
the wick is disposed on an inside of the heat receiver.

5. The cooling device according to claim 3, wherein
the wick is disposed on an inside of the heat sink.

6. The cooling device according to claim 1, wherein
the heat receiver includes a heat receiving plate that is hollow, and
the air tube and the liquid tube are coupled to an end surface of the heat receiving plate.

7. The cooling device according to claim 1, wherein
the heat sink has a heat radiation plate that is hollow, and
wherein the air tube and the liquid tube are coupled to an end surface of the heat radiation plate.

8. The cooling device according to any one of claim 1, further comprising:
a case that covers the heat sink.

9. The cooling device according to claim 8, wherein
the case is made of metal, and
a phase-change fluid is stored between the heat sink and the case, the phase-change fluid being vaporized by heat received from the heat sink and being liquefied by heat radiated to the case.

10. The cooling device according to claim 8, further comprising:
a liquid tube cover that covers a portion of the liquid tube on the side of heat sink.

11. The cooling device according to claim 9, further comprising:
a liquid tube cover that covers a portion of the liquid tube on the side of heat sink, wherein
the liquid tube cover is made of metal, and
the phase-change fluid is stored between the liquid tube and the liquid tube cover.

12. The cooling device according to claim 11, wherein
an inside of the case and an inside of the liquid tube cover are communicated.

13. The cooling device according to any one of claims 8, further comprising:
an air tube cover that covers a portion of the air tube on the side of heat sink.

14. An electronic apparatus comprising:
an electronic component; and
a cooling device including:
a heat receiver in which a working fluid is enclosed,
a heat sink in which the working fluid is enclosed,
an air tube made of metal so as to have flexibility, the air tube coupling the heat receiver and the heat sink, the air tube in which the working fluid of a gas phase flows through, and
a liquid tube made of metal so as to have flexibility, the liquid tube coupling the heat receiver and the heat sink, the liquid tube in which the working fluid of a liquid phase flows through.

15. The electronic apparatus according to claim 14, further comprising:
a housing in which the electronic component is housed, wherein
the heat receiver is provided on an inside of the housing,
the heat sink is provided on an outside of the housing,
the air tube pass through first hole of the housing, and
the liquid tube pass through second hole of the housing.

16. The electronic apparatus according to claim 15, further comprising:
a case that covers the heat sink;
a liquid tube cover that covers a portion of the liquid tube positioned on an outside of the housing; and
an air tube cover that covers a portion of the air tube positioned on the outside of the housing.

17. The electronic apparatus according to claim 15, further comprising:
a first sealing member that seals between the air tube and the first hole, and
a second sealing member that seals between the liquid tube and the second hole.

18. The electronic apparatus according to any one of claims 14, wherein
the liquid tube is filled with a wick exerting a capillary force to the working fluid.

19. The electronic apparatus according to claim 18, wherein
the heat sink is positioned on a lower side further than the heat receiver.
